(19) United States
(12) Patent Application Publication
(10) Pub. No.: US 2026/0104453 A1
(43) Pub. Date: Apr. 16, 2026

(54) HIGH-SPEED ELECTRICAL TESTING SYSTEM APPLIED TO PRINTED DISPLAY PANEL

(71) Applicant: FUZHOU UNIVERSITY, Fuzhou (CN)

(72) Inventors: Chaoxing WU, Fuzhou (CN); Hao SU, Fuzhou (CN); Yongai ZHANG, Fuzhou (CN); Xiongtu ZHOU, Fuzhou (CN); Yun YE, Fuzhou (CN); Tailiang GUO, Fuzhou (CN)

(21) Appl. No.: 19/355,154

(22) Filed: Oct. 10, 2025

Related U.S. Application Data
(63) Continuation of application No. PCT/CN2024/126339, filed on Oct. 22, 2024.

(30) Foreign Application Priority Data
Feb. 23, 2024 (CN) 202410201485.4

(51) Int. Cl. G01R 31/309

(52) U.S. Cl. CPC G01R 31/309

(57) ABSTRACT

The present invention discloses high-speed electrical testing system applied to printed display panel The system includes: a first substrate containing a conductive layer, and a detection probe array disposed opposite to the conductive layer. The printed display panel has a sandwich-layered structure comprising an anode terminal, a light-emitting layer, and a cathode terminal for its light-emitting pixels. The detection probe array and the conductive layer are electrically connected to a high-frequency AC power supply module, which supplies power to form a first alternating electric field between the detection probe array and the conductive layer. This first alternating electric field causes the printed display panel to exhibit electroluminescence. An electrical signal measurement module is disposed adjacent to the conductive layer, and an optical signal measurement module is disposed on one side of the first substrate. The present invention improves detection efficiency while avoiding damage to the printed display panel during detection.

### CROSS-REFERENCE TO RELATED APPLICATIONS

This application is a continuation of International Application No. PCT/CN2024/126339, filed on Oct. 22, 2024, which claims priority to Chinese Patent Application No. 202410201485.4, filed with the China National Intellectual Property Administration on Feb. 23, 2024, both of which are hereby incorporated by reference in their entireties.

### TECHNICAL FIELD

The present invention relates to the technical field of testing printed display panels, and particularly to a high-speed electrical testing system applied to printed display panel.

### BACKGROUND

Quantum dot light-emitting technology (QLED) and organic electroluminescent technology (OLED) are emerging research hotspots in flat-panel displays in recent years. The application value of these technologies in displays has attracted widespread attention from professionals in related fields, and major display manufacturers have released numerous high-end electronic products such as displays and smartphones based on these technologies. When QLED and OLED are used as array displays, screen components, or even semiconductor lighting, the use of unsorted QLED/OLED pixels can result in non-uniformity due to the human eye's sensitivity to color wavelength and brightness, thereby affecting visual effects. Both wavelength non-uniformity and brightness non-uniformity can cause user discomfort. This is undesirable for display device manufacturers and unacceptable to users. Therefore, QLED/OLED pixels must be tested before being applied in display devices. Current detection methods mostly involve probe testing, which is contact-based detection. However, probe testing requires contact between probes and the electrodes of QLED/OLED, potentially causing damage to the electrodes. As the size of individual chips used in display devices becomes smaller and the number of QLED/OLED pixels required for a single display increases, the efficiency of probe testing cannot meet the demands of mass QLED/OLED pixel detection. Furthermore, after a QLED/OLED panel is manufactured, if defective pixels are found during detection, they can only be removed by laser ablation. Bad pixel repair can only proceed after all defective pixels are removed. This traditional detection method significantly increases time and consumable costs during the detection process.

### SUMMARY

In view of the above-mentioned defects in the prior art, the technical problem to be solved by the present invention is to provide a high-speed electrical testing system applied to printed display panel, aiming to improve detection efficiency while avoiding damage to the printed display panel during detection.

To achieve the above purpose, the present invention provides a high-speed electrical testing system applied to printed display panel. The system includes: a first substrate comprising a conductive layer; a detection probe array disposed opposite to the conductive layer, wherein during detection of the printed display panel, the printed display panel is disposed between the first substrate and the detection probe array, and wherein light-emitting pixels of the printed display panel have a sandwich-layered structure comprising an anode terminal, a light-emitting layer, and a cathode terminal; a high-frequency AC power supply module electrically connected to both the detection probe array and the conductive layer, the high-frequency AC power supply module configured to supply power to form a first alternating electric field between the detection probe array and the conductive layer, the first alternating electric field causing the printed display panel to exhibit electroluminescence when a first direction from the anode terminal to the cathode terminal of a light-emitting pixel coincides with an electric field direction of the first alternating electric field; an electrical signal measurement module disposed adjacent to the conductive layer and configured to collect corresponding electrical signal information of the printed display panel; an optical signal measurement module disposed on one side of the first substrate and configured to collect corresponding light emission information of the printed display panel; an electrically controlled displacement module configured to carry and transport the first substrate or the detection probe array to align the detection probe array with the printed display panel during detection. The high-speed electrical testing system is configured as follows: control the optical signal measurement module to collect the light emission information during a half-cycle corresponding to a downward electric field direction of the first alternating electric field, in response to the anode terminal of each light-emitting pixel in the printed display panel being located above the cathode terminal; otherwise, control the optical signal measurement module to collect the light emission information during a half-cycle corresponding to an upward electric field direction of the first alternating electric field.

Optionally, the light-emitting pixels of the printed display panel comprise a deposited functional layer and the light-emitting layer, and the system is configured to detect the printed display panel without depositing metal electrodes.

Optionally, the deposited functional layer includes an anode, and the system is configured to detect the printed display panel without requiring a cathode.

Optionally, the deposited functional layer includes a cathode, and the system is configured to detect the printed display panel without requiring an anode.

Optionally, a distance between the detection probe array and the printed display panel during detection is maintained between 0.5 mm and 2 mm, and a supply voltage of the high-frequency AC power supply module is approximately 4000V.

Optionally, the detection probe array comprises a plurality of arrayed detection probes, each detection probe having a corresponding detection switch, and each detection probe corresponding to one light-emitting pixel; and the detection probe array controls the detection switches such that adjacent detection probes are activated for detection during different time periods.

Optionally, the electrically controlled displacement module is specifically configured to transport the first substrate or the detection probe array after detection of a corresponding detection area of the printed display panel is completed, so that a next detection area corresponds to the first substrate or the detection probe array.

Optionally, a bottom area of a detection probe is not less than an area of a single light-emitting pixel of the first substrate to be detected, and the detection probe array corresponds to at least one light-emitting pixel per detection.

Optionally, the high-speed electrical testing system operates in a water-and oxygen-free environment.

Optionally, a detection probe comprises a planar conductive substrate and a supporting structure, and an area of the planar conductive substrate is not less than an area of a single light-emitting pixel of the first substrate to be detected.

### BRIEF DESCRIPTION OF THE DRAWINGS

FIG. 1 is a schematic structural diagram of high-speed electrical testing system applied to printed display panel according to an embodiment of the present invention.

FIG. 2 is a schematic structural diagram of a detection probe array according to an embodiment of the present invention.

FIG. 3 is a schematic diagram of a single detection probe according to an embodiment of the present invention.

FIG. 4 is a schematic structural diagram of a detection probe according to an embodiment of the present invention.

FIG. 5 is a schematic system structural diagram when an optical signal measurement module is below the first substrate according to an embodiment of the present invention.

FIG. 6 is a schematic structural diagram of a detection probe with an optical signal measurement module integrated inside according to an embodiment of the present invention.

FIG. 7 is a schematic system structural diagram with an optical signal measurement module inside the detection probe according to an embodiment of the present invention.

FIG. 8 is a schematic structural diagram of a detection probe with micro-nano structures according to an embodiment of the present invention.

FIG. 9 is a schematic structural diagram of a cylindrical detection probe array according to an embodiment of the present invention.

FIG. 10 is a schematic structural diagram of an OLED according to an embodiment of the present invention.

FIG. 11 is a three-dimensional schematic structural diagram of high-speed electrical testing system applied to printed display panel according to an embodiment of the present invention.

### DESCRIPTION OF EMBODIMENTS

The present invention discloses high-speed electrical testing system applied to printed display panel. Those skilled in the art can refer to the content herein and make appropriate improvements to technical details. It is specifically pointed out that all similar substitutions and modifications are obvious to those skilled in the art and are deemed to be included within the scope of the present invention. The method and application of the present invention have been described through preferred embodiments. Relevant personnel can obviously modify or appropriately change and combine the methods and applications described herein without departing from the content, spirit, and scope of the present invention to implement and apply the technology of the present invention.

Through research, the applicant has found that: Existing probe testing for printed display panels requires contact between probes and the electrodes of QLED/OLED, potentially causing damage to the electrodes. As the size of individual chips used in display devices becomes smaller and the number of QLED/OLED pixels required for a single display increases, the efficiency of probe testing cannot meet the demands of mass QLED/OLED pixel detection. Contactless detection can solve some problems, but continuous collection of optical signals may reduce detection accuracy.

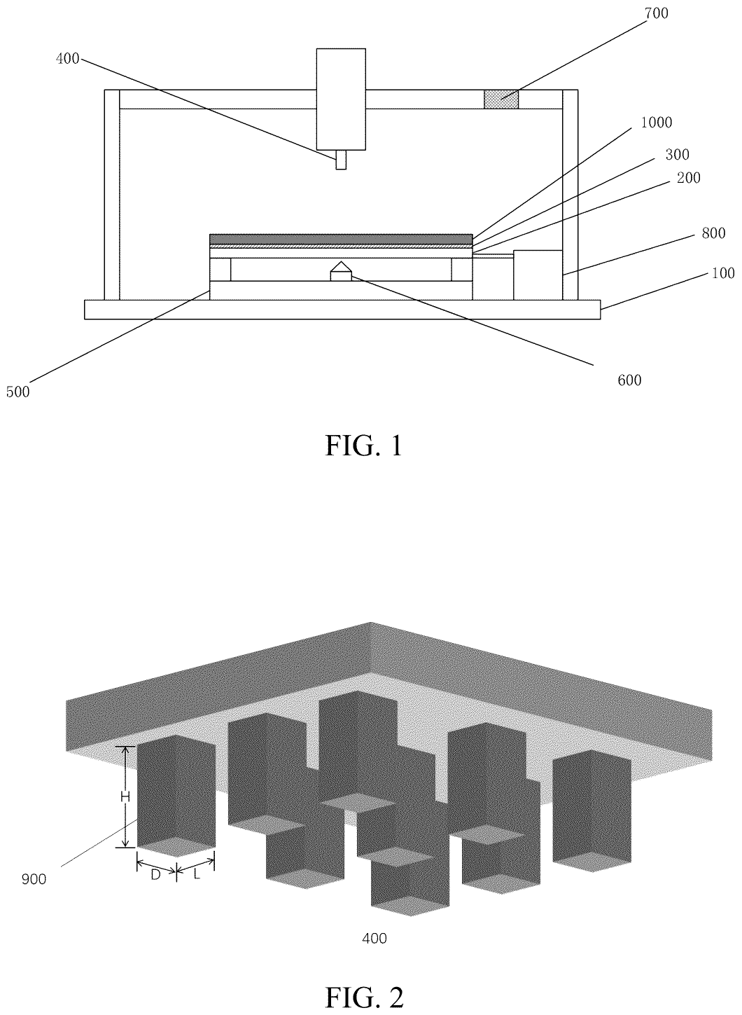

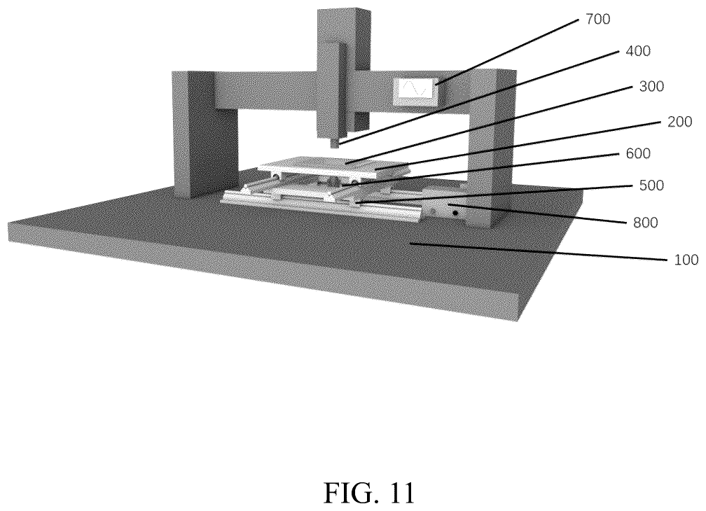

Therefore, an embodiment of the present invention provides high-speed electrical testing system applied to printed display panel (1000), as shown in FIGS. 1 to 11. The system includes: a first substrate (200) containing a conductive layer (300); a detection probe array (400) disposed opposite to the conductive layer (300); wherein during detection of the printed display panel (1000), the printed display panel (1000) is disposed between the first substrate (200) and the detection probe array (400); and light-emitting pixels of the printed display panel (1000) have a sandwich-layered structure comprising an anode terminal, a light-emitting layer, and a cathode terminal.

The detection probe array (400) includes at least one detection probe (900). The detection probe array (400) and the conductive layer (300) are electrically connected to a high-frequency AC power supply module (800). The high-frequency AC power supply module (800) supplies power to form a first alternating electric field between the detection probe array (400) and the conductive layer (300). This first alternating electric field causes the printed display panel (1000) to exhibit electroluminescence when a first direction from the anode terminal to the cathode terminal of a light-emitting pixel coincides with the electric field direction of the first alternating electric field.

An electrical signal measurement module (700) is disposed adjacent to the conductive layer (300) and configured to collect corresponding electrical signal information of the printed display panel (1000). An optical signal measurement module (600) is disposed on one side of the first substrate (200) and configured to collect corresponding light emission information of the printed display panel (1000). The system further includes an electrically controlled displacement module (500) configured to carry and transport the first substrate (200) or the detection probe array (400) to align the detection probe array (400) with the printed display panel (1000) during detection.

The high-speed electrical testing system is configured to: control the optical signal measurement module (600) to collect the light emission information during a half-cycle corresponding to a downward electric field direction of the first alternating electric field, in response to the anode terminal of each light-emitting pixel in the printed display panel (1000) being located above the cathode terminal; otherwise, control the optical signal measurement module (600) to collect the light emission information during a half-cycle corresponding to an upward electric field direction of the first alternating electric field.

It should be noted that the side of the light-emitting layer for depositing the anode is called the anode side. The anode side includes states where the anode and functional layers on this side are fully prepared or not fully prepared; the term “anode side” refers only to the direction, not necessarily that the anode is fully prepared. The side of the light-emitting layer for depositing the cathode is called the cathode side. The cathode side includes states where the cathode and functional layers on this side are fully prepared or not fully prepared; the term “cathode side” refers only to the direction, not necessarily that the cathode is fully prepared.

The sandwich layered structure refers to its multi-layer structure, composed of multiple layers of organic and/or inorganic materials, resembling a sandwich. For example, an OLED structure typically includes the following layers, as shown in FIG. 10: Anode: The top electrode of the OLED, usually a transparent material like glass or polymer; Hole Injection Layer (HIL): A thin layer between the anode and the hole transport layer, responsible for injecting holes into the hole transport layer; Hole Transport Layer (HTL): Transports holes towards the emissive layer; Emissive Layer (EML): The core part of the OLED, containing different emissive materials to produce light of various colors; Electron Transport Layer (ETL): Transports electrons towards the emissive layer; Electron Injection Layer (EIL): A thin layer between the emissive layer and the cathode, responsible for injecting electrons into the emissive layer; Cathode: The bottom electrode of the OLED, which is usually made of metal material.

These layers work together to enable the OLED to emit light. When a voltage is applied between the anode and cathode, holes and electrons are injected into the emissive layer, where they combine to form excitons that release energy as light.

The embodiment of the present invention drives the directional transport of carriers within the light-emitting pixels of the printed display panel (1000) by generating the first alternating electric field, causing electroluminescence. It then collects electrical signal information and optical signal information from the printed display panel (1000) to determine whether each light-emitting pixel is qualified. This contactless detection avoids damage to the printed display panel (1000) and accelerates detection efficiency.

In a specific embodiment, the high-speed electrical testing system further includes: a system base (100) for carrying various components.

In a specific embodiment, the electrical signal measurement module (700) collects corresponding electrical signal information of the printed display panel (1000), and the optical signal measurement module (600) collects corresponding light emission information. The quality of the detected light-emitting pixel is determined based on both the electrical signal information and the light emission information. The light emission information includes brightness, wavelength, full width at half maximum (FWHM), and imaging. The electrical signal information includes current, voltage, and frequency.

In a specific embodiment, the light-emitting pixels of the printed display panel (1000) comprise a deposited functional layer and the light-emitting layer, and the high-speed electrical testing system detects the printed display panel (1000) without depositing metal electrodes.

It should be noted that if faults are discovered only after the light-emitting pixels are fully processed, significant resources and process steps are wasted. This embodiment allows detection of light-emitting pixels before the metal electrode deposition step, enabling timely fault discovery and avoiding wasting resources and process steps on subsequently depositing metal electrodes for faulty pixels.

Further, the deposited functional layer includes an anode, and the system detects the printed display panel (1000) without requiring a cathode.

Further, the deposited functional layer includes a cathode, and the system detects the printed display panel (1000) without requiring an anode.

In a specific embodiment, the distance between the detection probe array and the printed display panel during detection is maintained between 0.5 mm and 2 mm, and the supply voltage of the high-frequency AC power supply module is approximately 4000V. This produces a field strength of 2000 V/mm to 8000 V/mm.

It should be noted that providing sufficient voltage and maintaining a reasonable distance generates an electric field strong enough to guide the directional transport of carriers within the light-emitting pixels.

In a specific embodiment, the detection probe array (400) comprises a plurality of arrayed detection probes (900). Each detection probe (900) has a corresponding detection switch, and each detection probe (900) corresponds to one light-emitting pixel. The detection probe array (400) controls the detection switches so that adjacent detection probes (900) are activated for detection during different time periods.

It should be noted that this embodiment effectively avoids mutual interference during detection caused by adjacent light-emitting pixels emitting light simultaneously due to close proximity, thereby affecting optical information collection.

In a specific embodiment, the electrically controlled displacement module (500) is specifically configured to transport the first substrate (200) or the detection probe array (400) after detection of a corresponding detection area of the printed display panel (1000) is completed, so that a next detection area corresponds to the first substrate (200) or the detection probe array (400).

It should be noted that printed display panels (1000) are often large, making it difficult to cover the entire light-emitting pixel area with one detection probe array (400). Therefore, detection is performed area-by-area, using the electrically controlled displacement module (500) to ensure every light-emitting pixel is detected.

In a specific embodiment, the bottom area of a detection probe (900) is not less than the area of a single light-emitting pixel of the first substrate (200) to be detected. The detection probe array (400) corresponds to at least one light-emitting pixel per detection.

It should be noted that the bottom area of the detection probe (900) being not less than the area of a single light-emitting pixel ensures effective coverage of the pixel, avoiding missed detection or erroneous detection due to incomplete coverage.

In a specific embodiment, the high-speed electrical testing system operates in a water-and oxygen-free environment.

It should be noted that a water-and oxygen-free environment prevents the first alternating electric field from being affected by moisture in the air.

In a specific embodiment, a detection probe (900) comprises a planar conductive substrate and its supporting structure. The area of the planar conductive substrate is not less than the area of a single light-emitting pixel of the first substrate (200) to be detected.

In a specific embodiment, high-speed electrical detection steps using the system are as follows:
place the display panel to be tested on the upper surface of the conductive layer (300);
under the drive of the electrically controlled displacement module (500), position the detection probe array (400) and the first substrate (200) such that the detection probe array (400) maintains a certain distance from the printed display panel (1000) and achieves maximum coupling area with the pixel array on the printed display panel (1000);
the high-frequency AC power supply module (800) applies a high-frequency electrical signal between the conductive layer (300) (or electrodes on the display panel to be detected) and the detection probe array (400), causing multiple pixels coupled to the detection probe array (400) to exhibit electroluminescence. The optical signal measurement module records the light emission information of the detected pixels, and the electrical signal measurement module (700) records the electrical signals of the detected pixels;
using the electrically controlled displacement module (500), move the detection probe array (400) while keeping its vertical distance from the display panel to be tested unchanged and ensuring maximum coupling area with the printed display panel (1000), along a certain direction while maintaining continuous coupling with the printed display panel (1000), until the detection probe array (400) moves to an adjacent undetected area. The optical signal measurement module records the light emission information of the pixels in the area to be detected, and the electrical signal measurement module (700) records the electrical signals of the detected pixels;
repeat steps (3) and (4) until all pixels on the surface of the display panel to be tested are detected.

In a specific embodiment, optical lens groups and optical fibers for optical signal measurement (optical signal measurement module 600) can be located inside the detection probe array (400). The planar conductive substrate of the detection probe (900) has a transmittance of 30% to 90% in the visible light range. Sufficient transmittance ensures light emission information can be better collected, improving detection accuracy.

In a specific embodiment, the optical signal measurement module and the detection probe array (400) can be located on the same side or opposite sides of the display panel to be detected.

In a specific embodiment, the detection probe array (400) can cover a functional layer. The functional layer can be a conductive material, a semiconductor material, an insulating material, or a composite structure thereof.

In a specific embodiment, the bottom surface shape of a detection probe (900) can be regular shapes such as square, rectangle, or circle, or any polygonal shape capable of coupling with multiple QLED/OLED pixels on the printed display panel (1000). The area of the planar conductive substrate of the detection probe (900) ranges from 1 μm² to 50 cm².

During the detection of QLED/OLED pixels, the detection probe array (400) is parallel to the printed display panel (1000) and coupled to it with maximum coupling area, enabling simultaneous electroluminescence from multiple QLED/OLED pixels.

Further, the optical signal measurement module must be capable of obtaining specific data such as brightness, wavelength, and FWHM of the detected QLED/OLED panel. The electrical signal measurement module (700) must be capable of obtaining electrical data such as current and voltage of the detected QLED/OLED panel.

Further, the outer surface of the planar conductive substrate of the detection probe (900) can be covered with a functional layer. The functional layer can be a conductive material, a semiconductor material, or an insulating material.

Further, the area of the planar conductive substrate of the detection probe (900) is 1 μm² to 50 cm².

Further, the area of the pixel array detected by the detection probe array (400) in one detection cycle can be larger than, equal to, or smaller than the area of the printed display panel (1000).

Further, the electrically controlled displacement module (500) must be capable of selectively moving and rotating the detection probe array (400) in three-dimensional space.

Further, the electrical signal applied by the high-frequency AC power supply module (800) between the conductive layer (300) and the detection probe array (400) is an alternating voltage.

Further, the conductive layer (300) can be disposed on the upper surface or the lower surface of the substrate.

Further, the detected QLED/OLED panel can include, but is not limited to, panels disposed on sapphire surfaces, panels disposed on other transitional substrate substrates, or panels disposed on driving backplanes.

Further, after the detection probe array (400) detects a specific planar-distributed QLED/OLED pixel array, the high-frequency AC power supply module (800) can either continue supplying power until detection of all pixels on the printed display panel (1000) surface is complete; or it can interrupt power supply and resume only after the detection probe array (400) moves to another undetected area.

Further, the bottom surface shape of the detection probe (900) can be regular shapes such as square, rectangle, or circle, or any polygonal shape capable of coupling with multiple QLED/OLED pixels on the printed display panel (1000).

The embodiment of the present invention achieves efficient detection by driving the detection probe array (400) via the electrically controlled displacement module (500) to achieve maximum coupling area with multiple QLED/OLED pixels on the surface of the printed display panel (1000), enabling simultaneous detection of QLED/OLED pixels without depositing electrodes.

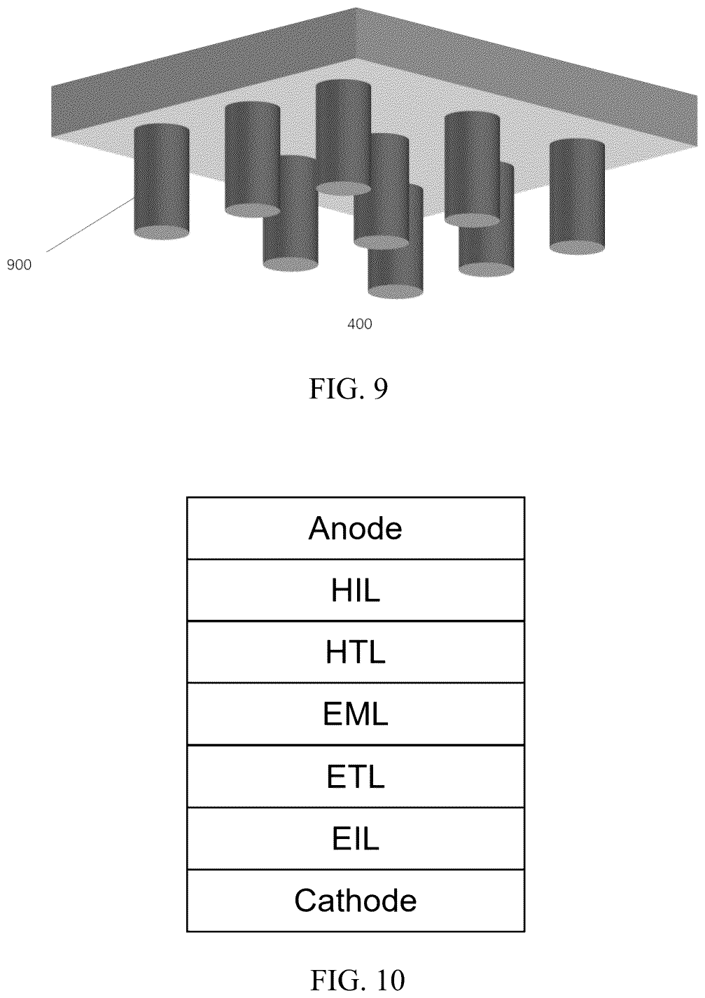

In a specific embodiment, the specific shape of the detection probe (900) is not fixed. It can be regular geometric bodies like a cuboid (as shown in FIG. 2) or a cylinder (as shown in FIG. 9), or any irregular geometric body capable of coupling with multiple QLED/OLED pixels on the printed display panel (1000). This embodiment preferably uses cuboid conductive material as the detection probe (900).

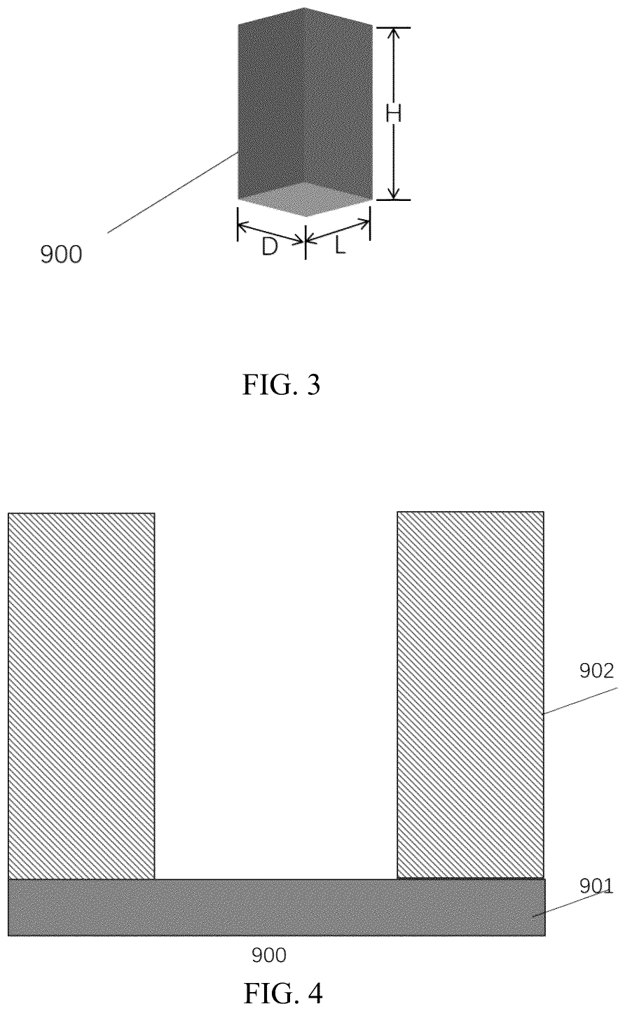

During testing, place the printed display panel (1000) on the upper surface of the conductive layer (300), and place the detection probe (900) above the printed display panel (1000) maintaining a certain distance. In this embodiment, the length (D), width (L), and height (H) of the preferred detection probe (900) are 50 μm, 50 μm, and 100 μm, respectively (as shown in FIG. 3).

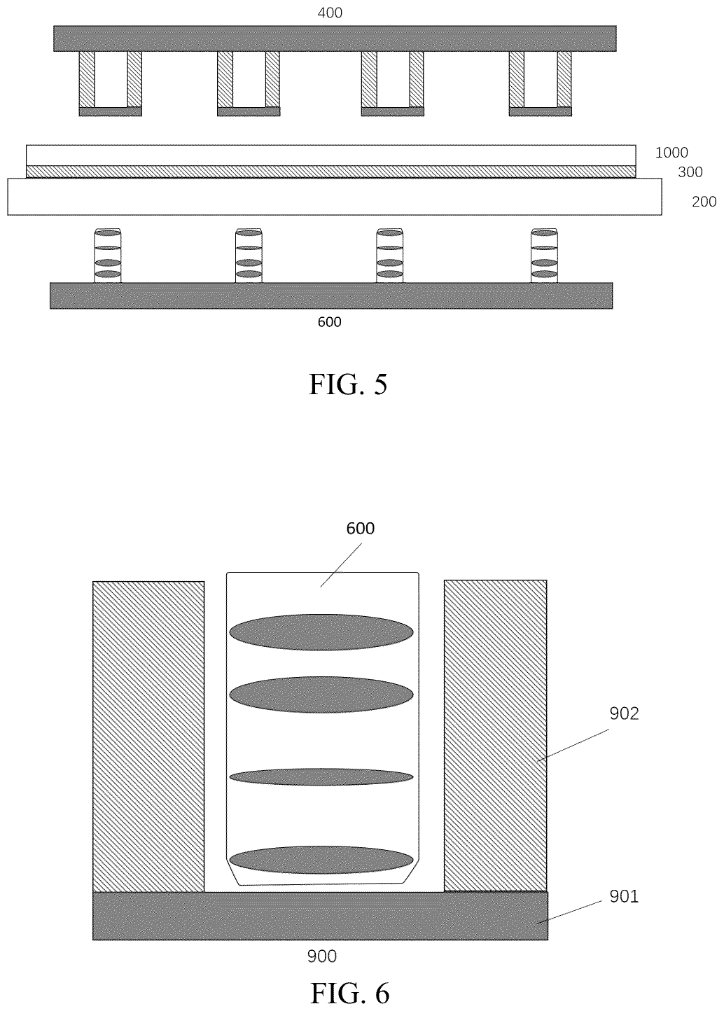

To ensure each detection probe (900) can activate one or more QLED/OLED pixels, the detection probe (900) comprises a planar conductive substrate (901) whose bottom area is not less than the area of a single pixel on the printed display panel (1000), and its supporting structure (902) (as shown in FIG. 4).

The optical signal measurement module (600) can be integrated with the detection probe (900). The optical signal measurement module can be placed inside the detection probe (900). In this case, the planar conductive substrate (901) of the detection probe (900) has a transmittance of 30% to 90% for visible light (as shown in FIG. 5).

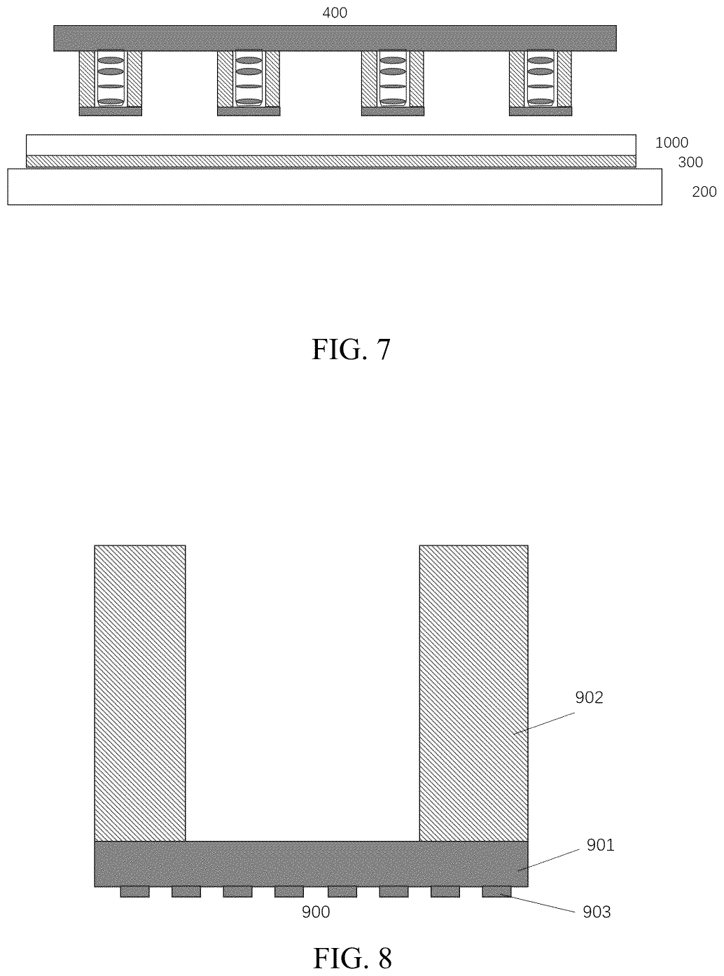

The detection probe array (400) integrating the optical signal measurement module (600) is disposed above the printed display panel (1000), achieving coupling with multiple pixels on the display panel to be tested and collecting optical signals (as shown in FIG. 6).

In a specific embodiment, the optical signal measurement module (600) is not integrated with the detection probe (900). In this case, the optical signal measurement module (600) and the detection probe array (400) are disposed on opposite sides of the printed display panel (1000), respectively achieving optical signal collection and coupling with multiple pixels on the display panel to be tested (as shown in FIG. 7).

In a specific embodiment, the planar conductive substrate (901) of the detection probe (900) has micro-nano structures (903). These structures alter the electric field distribution between the detection probe (900) and the conductive layer (300) to obtain more precise detection results (as shown in FIG. 8).

In a specific embodiment, the geometric shape of the detection probe (900) is set as a cylinder (as shown in FIG. 9). The cylindrical detection probe (900) must function to couple with one or more QLED/OLED pixels on the printed display panel (1000).

The system of the present invention embodiment includes a first substrate (200) containing a conductive layer (300) and a detection probe array (400) disposed opposite to the conductive layer (300). The detection probe array (400) includes at least one detection probe (900). The detection probe array (400) and the conductive layer (300) are electrically connected to a high-frequency AC power supply module (800), which supplies power to form a first alternating electric field between the detection probe array (400) and the conductive layer (300). This first alternating electric field causes the printed display panel (1000) to exhibit electroluminescence. The invention detects whether light-emitting pixels are qualified by using an electric field to guide directional transport of carriers within the light-emitting pixels, thereby achieving contactless detection and avoiding damage caused by contact detection. Simultaneously, compared to the probe testing of the prior art, one detection probe (900) in this embodiment can detect multiple light-emitting pixels, greatly improving detection efficiency. This embodiment has higher detection accuracy compared to optical microscopic imaging detection and electroluminescence detection.

The high-speed electrical testing system of this embodiment is configured to control the optical signal measurement module (600) to collect light emission information during the half-cycle when the electric field direction coincides with the correct biasing direction for the pixel structure (downward if anode is above cathode, upward otherwise). This controls the optical signal measurement module (600) to collect only when the pixels are supposed to be emitting light, effectively reducing energy waste from continuous collection. Simultaneously, collecting optical signals during the correct light emission period allows for fault exclusion of pixels emitting at the wrong time.

The light-emitting pixels of the printed display panel (1000) of this embodiment comprise a deposited functional layer and the light-emitting layer, and the high-speed electrical testing system detects the printed display panel (1000) without depositing metal electrodes. Detecting before metal electrode deposition allows timely discovery of faulty light-emitting pixels, effectively reducing process steps and resource waste compared to discovering errors only after complete pixel fabrication.

The detection probe array (400) of this embodiment comprises multiple arrayed detection probes (900), each detection probe (900) having a corresponding detection switch and each corresponding to one light-emitting pixel. The detection probe array (400) controls the detection switches such that adjacent detection probes (900) are activated during different time periods. This causes adjacent light-emitting pixels to emit light at different times, effectively avoiding mutual interference caused by simultaneous emission of adjacent pixels. This makes the detection by the optical signal measurement module (600) more precise and effectively improves the detection accuracy for light-emitting pixel faults.

In summary, the embodiment of the present invention can effectively avoid detection damage to the printed display panel (1000) while improving detection efficiency and accuracy.

It should be noted that in this document, relational terms such as “first” and “second” are used only to distinguish one entity or operation from another entity or operation, and do not necessarily require or imply any actual such relationship or order between them. Furthermore, the terms “comprise”, “include”, or any other variations thereof are intended to cover non-exclusive inclusion, so that a process, method, article, or device comprising a list of elements includes not only those elements but also other elements not explicitly listed, or elements inherent to such process, method, article, or device. Without further limitation, an element defined by the phrase “comprising a . . . ” does not preclude the presence of additional identical elements in the process, method, article, or device that includes the element.

The various embodiments in this specification are described in a related manner. Identical or similar parts between the various embodiments can be referred to each other. Each embodiment focuses on describing its differences from other embodiments. Especially for the system embodiments, since they are basically similar to the method embodiments, the description is relatively simple. Relevant parts can refer to the description in the method embodiments.

The above descriptions are only preferred embodiments of the present invention and are not intended to limit the scope of protection of the present invention. Any modification, equivalent replacement, or improvement made within the spirit and principles of the present invention shall be included within the scope of protection of the present invention.

The system of the present invention includes a first substrate containing a conductive layer and a detection probe array disposed opposite to the conductive layer. The detection probe array includes at least one detection probe. The detection probe array and the conductive layer are electrically connected to a high-frequency AC power supply module, which supplies power to form a first alternating electric field between the detection probe array and the conductive layer. This first alternating electric field causes the printed display panel to exhibit electroluminescence. The invention detects whether light-emitting pixels are qualified by using an electric field to guide directional transport of carriers within the light-emitting pixels, thereby achieving electroluminescence and contactless detection, avoiding damage caused by contact detection. Simultaneously, compared to the needle testing of the prior art, one detection probe in the present invention can detect multiple light-emitting pixels, greatly improving detection efficiency. The present invention has higher detection accuracy compared to optical microscopic imaging detection and electroluminescence detection.

The high-speed electrical testing system of the present invention is configured to control the optical signal measurement module to collect light emission information during the half-cycle when the electric field direction coincides with the correct biasing direction for the pixel structure (downward if anode is above cathode, upward otherwise). This controls the optical signal measurement module to collect only when the pixels are supposed to be emitting light, effectively reducing energy waste from continuous collection. Simultaneously, collecting optical signals during the correct light emission period allows for fault exclusion of pixels emitting at the wrong time (a fault condition where emission occurs during the opposite half-cycle, which might otherwise be misclassified as qualified).

The light-emitting pixels of the printed display panel of the present invention comprise a deposited functional layer and the light-emitting layer, and the high-speed electrical testing system detects the printed display panel without depositing metal electrodes. Detecting the panel before metal electrode deposition allows timely discovery of faulty light-emitting pixels, effectively reducing process steps and resource waste compared to discovering errors only after complete pixel fabrication.

The detection probe array of the present invention comprises multiple arrayed detection probes, each detection probe having a corresponding detection switch and each corresponding to one light-emitting pixel. The detection probe array controls the detection switches such that adjacent detection probes are activated during different time periods. This causes adjacent light-emitting pixels to emit light at different times, effectively avoiding mutual interference caused by simultaneous emission of adjacent pixels. This makes the detection by the optical signal measurement module more precise and effectively improves the detection accuracy for light-emitting pixel faults.

In summary, the present invention can effectively avoid detection damage to the printed display panel while improving detection efficiency and accuracy.

What is claimed is:

1. High-speed electrical testing system applied to printed display panel, comprising: a first substrate comprising a conductive layer; a detection probe array disposed opposite to the conductive layer, wherein during detection of the printed display panel, the printed display panel is disposed between the first substrate and the detection probe array, and wherein light-emitting pixels of the printed display panel have a sandwich layered structure comprising an anode terminal, a light-emitting layer, and a cathode terminal; a high-frequency AC power supply module electrically connected to both the detection probe array and the conductive layer, the high-frequency AC power supply module configured to supply power to form a first alternating electric field between the detection probe array and the conductive layer, the first alternating electric field causing the printed display panel to exhibit electroluminescence when a first direction from the anode terminal to the cathode terminal of a light-emitting pixel coincides with an electric field direction of the first alternating electric field; an electrical signal measurement module disposed adjacent to the conductive layer and configured to collect corresponding electrical signal information of the printed display panel; an optical signal measurement module disposed on one side of the first substrate and configured to collect corresponding light emission information of the printed display panel; and an electrically controlled displacement module configured to carry and transport the first substrate or the detection probe array to align the detection probe array with the printed display panel during detection. The high-speed electrical testing system is configured as follows: control the optical signal measurement module to collect the light emission information during a half-cycle corresponding to a downward electric field direction of the first alternating electric field, in response to the anode terminal of each light-emitting pixel in the printed display panel being located above the cathode terminal; otherwise, control the optical signal measurement module to collect the light emission information during a half-cycle corresponding to an upward electric field direction of the first alternating electric field.

2. The system according to claim 1, wherein the light-emitting pixels of the printed display panel comprise a deposited functional layer and the light-emitting layer, and wherein the system is configured to detect the printed display panel without depositing metal electrodes.

3. The system according to claim 2, wherein the deposited functional layer includes an anode, and wherein the system is configured to detect the printed display panel without requiring a cathode.

4. The system according to claim 2, wherein the deposited functional layer includes a cathode, and wherein the system is configured to detect the printed display panel without requiring an anode.

5. The system according to claim 1, wherein a distance between the detection probe array and the printed display panel during detection is maintained between 0.5 mm and 2 mm, and wherein a supply voltage of the high-frequency AC power supply module is approximately 4000V.

6. The system according to claim 1, wherein the detection probe array comprises a plurality of arrayed detection probes, each detection probe having a corresponding detection switch, and each detection probe corresponding to one light-emitting pixel; and wherein the detection probe array controls the detection switches such that adjacent detection probes are activated for detection during different time periods.

7. The system according to claim 1, wherein the electrically controlled displacement module is specifically configured to transport the first substrate or the detection probe array after detection of a corresponding detection area of the printed display panel is completed, so that a next detection area corresponds to the first substrate or the detection probe array.

8. The system according to claim 1, wherein a bottom area of a detection probe is not less than an area of a single light-emitting pixel of the first substrate to be detected, and wherein the detection probe array corresponds to at least one light-emitting pixel per detection.

9. The system according to claim 1, wherein the high-speed electrical testing system operates in a water-and oxygen-free environment.

10. The system according to claim 1, wherein a detection probe comprises a planar conductive substrate and a supporting structure, and wherein an area of the planar conductive substrate is not less than an area of a single light-emitting pixel of the first substrate to be detected.
